(19) United States
(12) Patent Application Publication
(10) Pub. No.: US 2026/0082937 A1
(43) Pub. Date: Mar. 19, 2026

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventor: ZiKang LIM, Petaling Jaya (MY)

(73) Assignee: Amkor Technology Singapore Holding Pte. Ltd., Valley Point #12-03 (SG)

(21) Appl. No.: 18/885,014

(22) Filed: Sep. 13, 2024

(51) Int. Cl. H01L 23/00; H01L 21/56; H01L 23/31; H01L 23/495

(52) U.S. Cl. CPC H10W 70/417; H10W 74/016; H10W 74/114; H10W 72/634; H10W 90/766

(57) ABSTRACT

In one example, an electronic device include a substrate with a die paddle and a contact. An electronic component is coupled to the die paddle. A conductive connect includes a foot portion coupled to the contact and a connect plate portion coupled to the electronic component. The foot portion includes a top side, a bottom side, and an outward lateral side. A chamfer extends inward from the outward lateral side and extends to the bottom side. A conductive adhesive couples the foot portions to contact and covers the chamfer and the bottom side. An encapsulant covers the electronic component, the conductive connect, and at least portions of the substrate. The chamfer improves the bonding integrity between the conductive connect and the substrate. Other examples and related methods are also disclosed herein.

### CROSS-REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1A shows a top plan and X-ray view of an example electronic device.

FIG. 1B shows a cross-sectional view of an example electronic device taken along line B-Bʹ in FIG. 1A.

FIG. 1C shows an enlarged view of a portion of an example electronic device in region 1C in FIG. 1B.

FIG. 1D shows an enlarged partial perspective view of an example conductive connect.

FIG. 1E shows an enlarged partial perspective view of an example conductive connect.

FIGS. 2A, 2B, 2C, 2D, 2E, 2F, 2G, 2H, 2I, 2J, and 2K show an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in the present disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to a mechanical coupling or an electrical coupling.

### DESCRIPTION

In some applications, electronic components, such as semiconductor devices, can be encapsulated within a package body where the semiconductor devices can be protected from hostile environments and electrical interconnection is enabled between the semiconductor devices and a next level assembly, such as a printed circuit board (PCB) or external assembly board. Components of an electronic package can generally comprise a conductive substrate such as a metal lead frame, one or more semiconductor devices, a bonding material for attaching the semiconductor devices to the lead frame, interconnects that electrically connect the semiconductor devices to individual leads of the lead frame, and an encapsulant material that covers the semiconductor devices and forms the external shape of an electronic package, commonly referred to as a package body.

In some examples, the metal lead frame can be manufactured by chemically etching or mechanical stamping a metal strip. A portion of the lead frame may be internal to the package body. Portions of the individual leads of the lead frame may extend outward from the package body or may be partially exposed from the package body to facilitate electrically coupling the electronic package to other components.

The present description includes, among other features, structures and associated methods that relate to packaged electronic devices including electronic components, such as power components, semiconductor components, and/or passive components. Examples of packaged electronic devices relevant to the present description can include, but are not limited to, a dual-row package, a MicroLead frame® type package (“MLF”) including a dual-row MLF type package (“DR-MLF”), dual flat no-lead package (“DFN”), small-outline no-lead package (“SON”), quad flat package (“QFP”), quad flat no-lead package (“QFN”), thin substrate chip scale packages (“tsCSP”), and advanced QFN package (“aQFN”). These packaged electronic devices can comprise a conductive substrate, such as metal lead frames with die attach paddles and leads. The conductive substrate can either be internal to or exposed from the encapsulant material. In some examples, the conductive substrate can comprise conductive materials such as copper (Cu), nickel (Ni), gold (Au), silver (Ag), palladium (Pd), iron (Fe). In some examples, the encapsulant can comprise insulating materials, such as epoxy mold compounds.

The present description is relevant to electronic devices that can perform various electrical functions including, but not limited to, power conversion. Such power conversion examples include, but are not limited to, half-bridge converters (e.g., including two switching elements) or full-bridge converters (e.g., including four switching elements). These power converters can comprise a variety of power conversion devices, such as alternating current (AC) to direct current (DC) converters, DC-DC converters, or DC-AC converters, and can convert or regulate power to suit various power requirements depending on the application.

In some examples, the present description relates to power semiconductor devices that use clip type interconnects to couple terminals or bond pads on the power semiconductor devices to one or more leads of a conductive substrate. In some examples, a chamfered edge or chamfer is provided at a foot portion of the clip that attaches to the leads, which was found through experimentation to improve the bonding integrity between the foot portion of the clip and the lead(s) the clip is attached to by facilitating a larger solder fillet proximate to the chamfered edge. This and other features of the present description improve the quality and reliability of packaged electronic devices.

Those skilled in the art will understand that although the following description focuses on various lead frame type substrate examples, a person skilled in the art will appreciate the same implementation principles can be applied to other types of package substrates.

In an example, an electronic device includes a substrate including a die paddle and a first contact spaced apart from the die paddle. An electronic component includes a first component side and a second component side opposite to the first component side and coupled to the die paddle. The electronic device includes a conductive adhesive. A conductive connect includes a foot portion coupled to the first contact with the conductive adhesive. The foot portion includes a top side, a bottom side opposite to the top side, an outward lateral side, and a chamfer that extends inward from the outward lateral side and terminates at a location at the bottom side. The conductive adhesive contacts the chamfer and the bottom side. The conductive connect includes a connect plate portion coupled to the first component side. An encapsulant covers the electronic component, the conductive connect, and at least portions of the substrate.

In an example, an electronic device includes a substrate including a die paddle, a first contact spaced apart from the die paddle and comprising a first contact top side, a first outward terminal coupled to the first contact, a second contact spaced apart from the die paddle, and a second outward terminal coupled to the second contact. An electronic component includes a first component side and a second component side opposite to the first component side and coupled to the die paddle. The electronic device includes a conductive adhesive. A conductive connect includes a foot portion coupled to the first contact with the conductive adhesive. The foot portion includes a top side, a bottom side opposite to the top side, an outward lateral side, an inward lateral side opposite the outward lateral side, and a chamfer that extends inward from the outward lateral side and terminates at a location at the bottom side. The conductive adhesive covers the chamfer and the bottom side and the top side of the foot portion is generally parallel to the first contact top side. The conductive connect includes a connect plate portion coupled to the first component side. An encapsulant covers the electronic component, the conductive connect, and at least portions of the substrate. The first outward terminal and the second outward terminal are exposed from the encapsulant.

In an example, a method of an electronic device includes providing a substrate including a die paddle and a first contact spaced apart from the die paddle. The method includes providing an electronic component including a first component side and a second component side opposite to the first component side and coupled to the die paddle. The method includes providing a conductive adhesive. The method includes providing a conductive connect including a foot portion coupled to the first contact with the conductive adhesive. The foot portion includes a top side, a bottom side opposite to the top side, an outward lateral side, and a chamfer that extends inward from the outward lateral side and terminates at a location at the bottom side. The conductive adhesive contacts the chamfer and the bottom side. The conductive connect includes a connect plate portion coupled to the first component side. The method includes providing an encapsulant covering the electronic component, the conductive connect, and at least portions of the substrate.

Other examples are included in the present disclosure. Such examples may be found in the figures, in the claims, or in the description of the present disclosure.

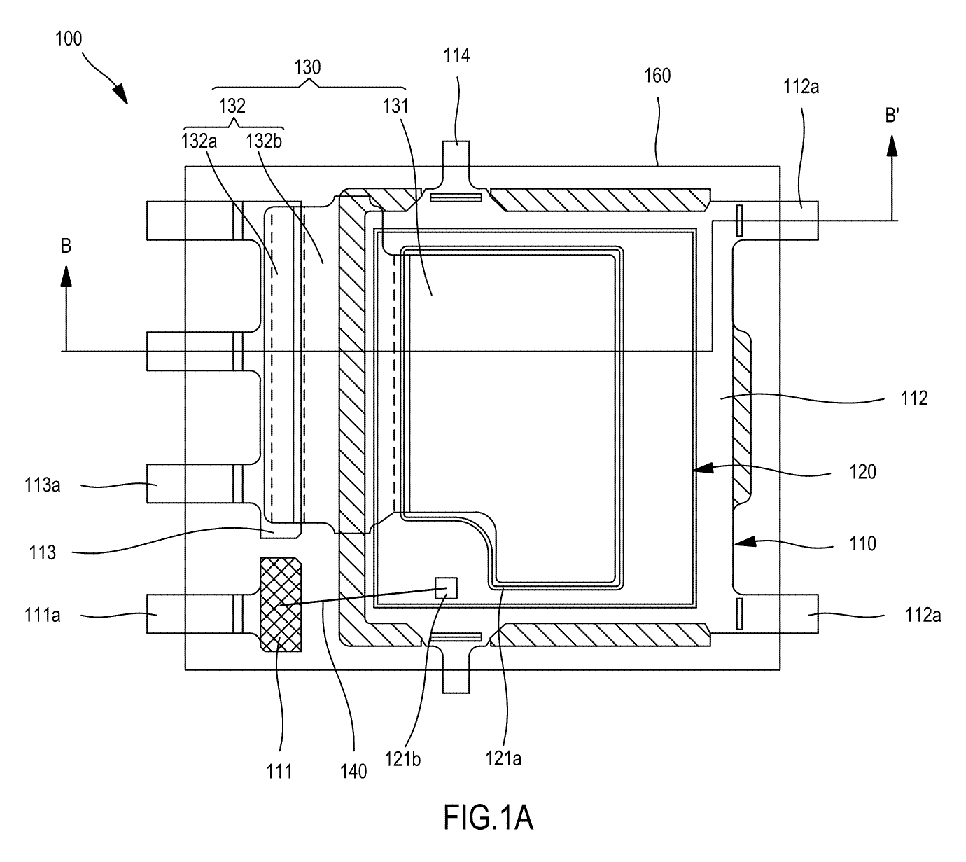

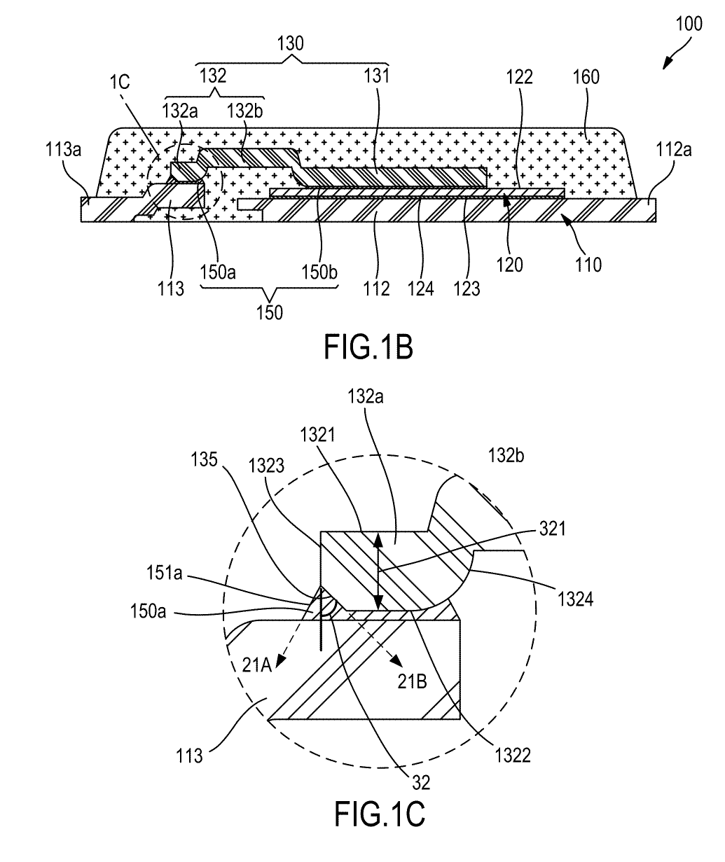

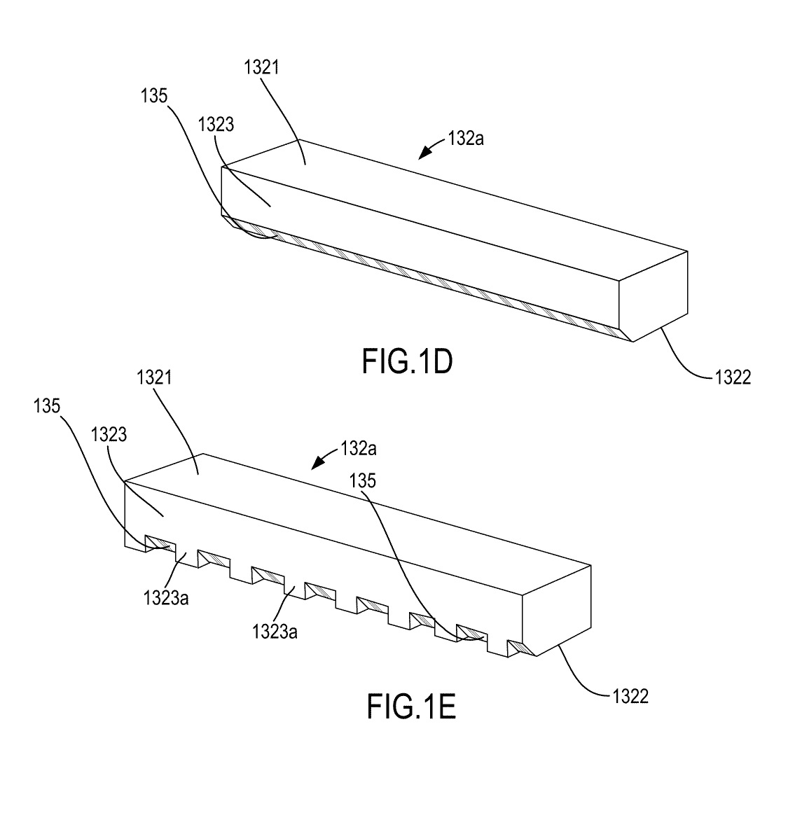

FIG. 1A shows a top plan and X-Ray view of an example electronic device 100, FIG. 1B shows a cross-sectional view of electronic device 100 taken along line B-B in FIG. 1A, and FIG. 1C shows an enlarged view of electronic device 100 in region 1C of FIG. 1B. In the example shown in FIGS. 1A, 1B, and 1C, electronic device 100 can comprise substrate 110, electronic component 120, conductive connect 130, interconnect 140, conductive adhesive 150, and encapsulant 160.

In some examples, substrate 110 can comprise gate contact 111, die paddle 112, source contact 113, and tie bar 114. In some examples, gate contact 111 can comprise gate outward terminal 111a, die paddle 112 can comprise one or more drain outward terminals 112a, and source contact 113 can comprise one or more source outward terminals 113a.

Electronic component 120 can comprise first side 122 and second side 123 opposite to the first side 122. Electronic component 120 can comprise contact pad 121a and contact pad 121b on first side 122. Contact pad 121a can comprise or be referred to as a source bond pad or source pad and contact pad 121b can comprise or be referred to as a gate bond pad or gate pad. In some examples, a conductive layer, such as a back metal layer, is provided on second side 123. In the present example, contact pad 121a and contact pad 121b are provided as part of electronic component 120 during a front-end wafer fabrication process. Conductive connect 130 can comprise connect plate portion 131 and connect leg 132 coupled to connect plate portion 131. In the present example, connect leg 132 comprises a foot portion 132a coupled to a leg portion 132b, which is coupled to connect plate portion 131.

In the present example, connect plate portion 131 is configured to couple to contact pad 121a on electronic component 120 and foot portion 132a is configured to couple to source contact 113. In some examples, conductive connect 130 can be attached to electronic component 120 and attached to source contact 113 of substrate 110 with conductive adhesive 150, which can include first conductive adhesive 150a and second conductive adhesive 150b. In some examples, connect plate portion 131 can be attached to contact pad 121a with first conductive adhesive 150a and foot portion 132a can be attached to source contact 113 with second conductive adhesive 150b.

In the present example, the top side of leg portion 132b resides on a first plane, the top side of foot portion 132a resides on a second plane, and the top side of connect plate portion 131 resides a third plane. The top side of leg portion 132b can comprise or be referred to as a leg portion top side and the top side of connect plate portion 131 can comprise or be referred to as a connect plate portion top side. In some examples, the first plane is above the second plane and the third plane. In some examples, the second plane is above the third plane. In the present example, leg portion 132b is offset upward with respect to connect plate portion 131 and offset upward with respect to foot portion 132a. In other examples, the top side of leg portion 132b, the top side of foot portion 132a, and the top side of connect plate portion 131 and all reside on the same plane and can be coplanar.

With reference to FIG. 1C, foot portion 132a comprises a top side 1321, a bottom side 1322 opposite to top side 1321, an outward lateral side 1323, and inward lateral side 1324 opposite to outward lateral side 1323. In accordance with the present description, outward lateral side 1323 comprises a chamfer 135 that extends inward from outward lateral side 1323 and terminates at a location at bottom side 1322. In accordance with the present description chamfer 135 is provided at an angle 32 with respect to outward lateral side 1323 that is greater than 0 degrees and less than 90 degrees. In some examples, angle 32 is between about 30 degrees and about 60 degrees. In some examples, angle 32 is between about 40 degrees and about 50 degrees. In some examples, angle 32 is about 45 degrees. Angle 32 can comprise or also be referred to as an inclination angle. Chamfer 135 can comprise or be referred to as a chamfered edge. In some examples, chamfer 135 comprises a straight or linear surface that is not a curved surface.

In some examples, chamfer 135 starts at a location on outward lateral side 1323 that is below the center point of outward lateral side 1323 and ends at a location on bottom side 1322 that is left of the center point of bottom side 1322. The center point of outward lateral side 1323 is an example of a first center point in a cross-sectional view and the center point of bottom side 1322 is an example of a second center point in the cross-sectional view. In some examples, chamfer 135 starts at a location on lateral side 35 that is proximate to the center point of outward lateral side 1323 and ends at a location on bottom side 1322 that is proximate to the center point of bottom side 1322. In some examples, chamfer 135 starts at a location on outward lateral side 1323 that is at, below, or above the center point of outward lateral side 1323 and ends at a location that is right of the center point of bottom side 1322. In some examples, chamfer 135 starts at location on outward lateral side 1323 that is at, below, or above the center point of outward lateral side 1323 and ends at a location that is at or left of the center point of bottom side 1322. In some examples, chamfer 135 does not start at a location on outward lateral side 1323 that is proximate to top side 1321 of foot portion 132a.

In some examples, chamfer 135 starts at a location on outward lateral side 1323 that leaves at least 25% to 75% of outward lateral side 1323 extending downward from top side 1321 where the amount of outward lateral side 1323 remaining is determined as a percentage of distance 321 between top side 1321 and bottom side 1322. In some examples, chamfer 135 starts at a location on outward lateral side 1323 that leaves at least 30% to 60% of outward lateral side 1323 extending downward from top side 1321. In some examples, chamfer 135 starts at a location on outward lateral side 1323 that leaves at least 50% of outward lateral side 1323 extending downward from top side 1321. In some examples, top side 1321 is generally parallel to bottom side 1322. In some examples, outward lateral side 1323 and inward lateral side 1324 comprise different shapes in cross-sectional view. In some examples, inward lateral side 1324 comprises a rounded shape or arcuate shape in cross-sectional view. In some examples, top side 1321 of foot portion 132a is generally parallel to the top side of source contact 113. In some examples, first conductive adhesive 150a contacts and covers chamfer 135 and bottom side 1322. In some examples, first conductive adhesive 150a completely covers the entire surface of chamfer 135. In some examples, first conductive adhesive 150a extends to contact cover a portion of outward lateral side 1323. In some examples, first conductive adhesive 150a comprises an outward side 151a the extends toward source contact 113 in a first direction 21A and chamfer 135 extends towards source contact 113 in a second direction 21B that is different than first direction 21A. In some examples, top side 1321 of foot portion is generally parallel to the top side of source contact 113, which is an example of a first contact top side.

FIG. 1D shows an enlarged partial perspective view of an example foot portion 132a where chamfer 135 is continuous and uninterrupted without breaks along the entire length of outward lateral side 1323. In other examples, chamfer 135 is discontinuous along the length of outward lateral side 1323. For example, FIG. 1E shows an enlarged partial perspective view of an example foot portion 132a where chamfer 135 comprises a plurality of individual chamfers 135 that are separated by portions 1323a of outward lateral side 1323. In the example shown FIG. 1E, portions 1323a of outward lateral side 1323 are devoid of chamfers 135. In some examples, one end of foot portion 132a can include a chamfer 135 and an opposing end can include a portion 1323a. In other examples, the opposing edges can include or be defined by a chamfer 135. In other examples, the opposing ends can include portion 1323a. In other examples, the opposing ends can include or be defined by chamfers 135. In other examples, the plurality of chamfers 135 can be separated by voids or gaps extending inward from bottom side 1322 of foot portion 132a. In a further example, chamfer 135 can comprise a single chamfer bounded on opposing ends of foot portion 132a by portions 1323a of outward lateral side 1323.

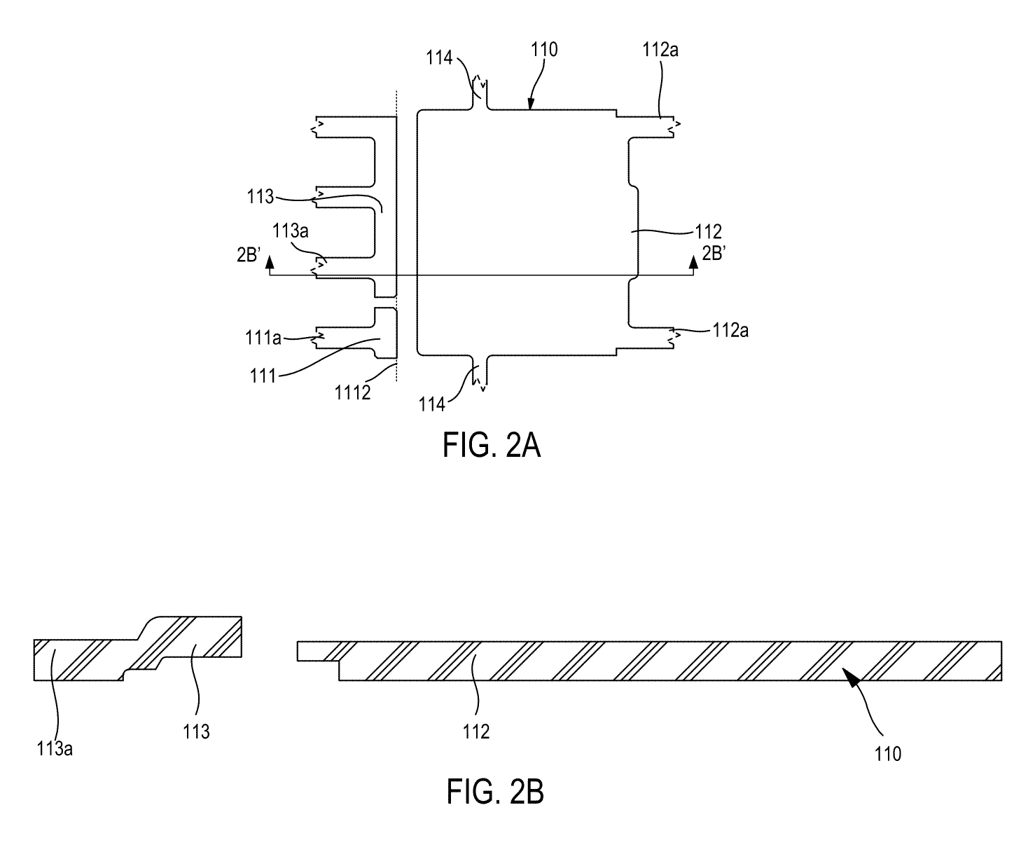

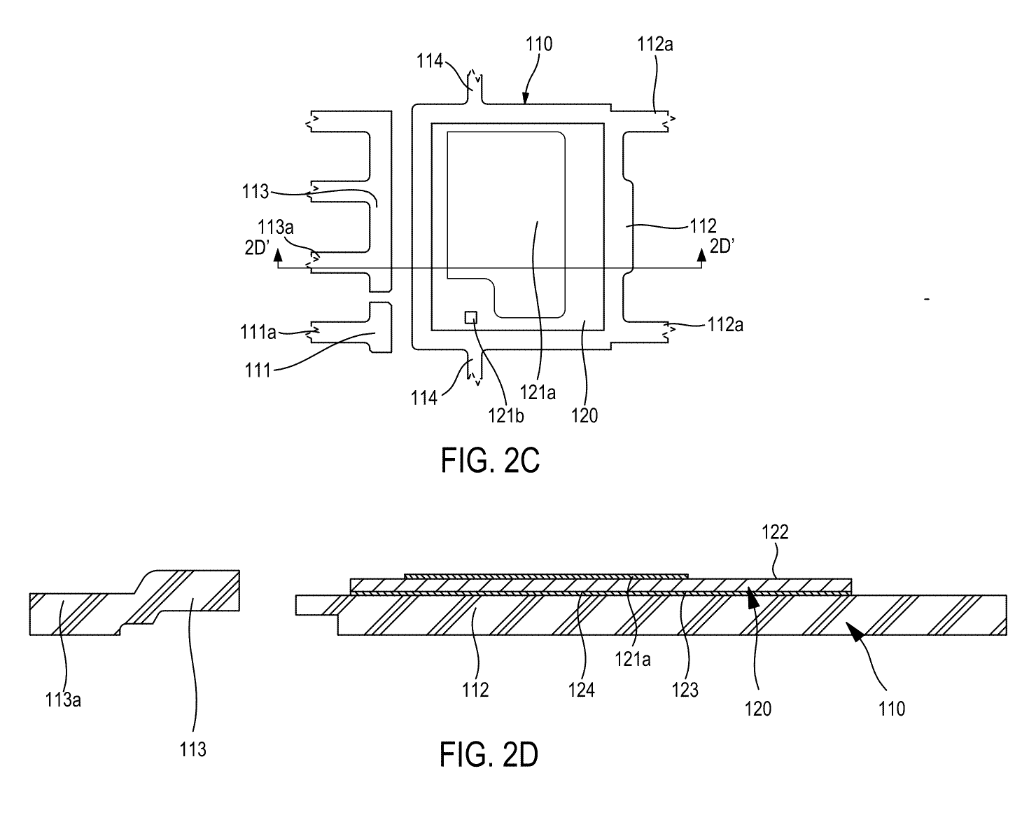

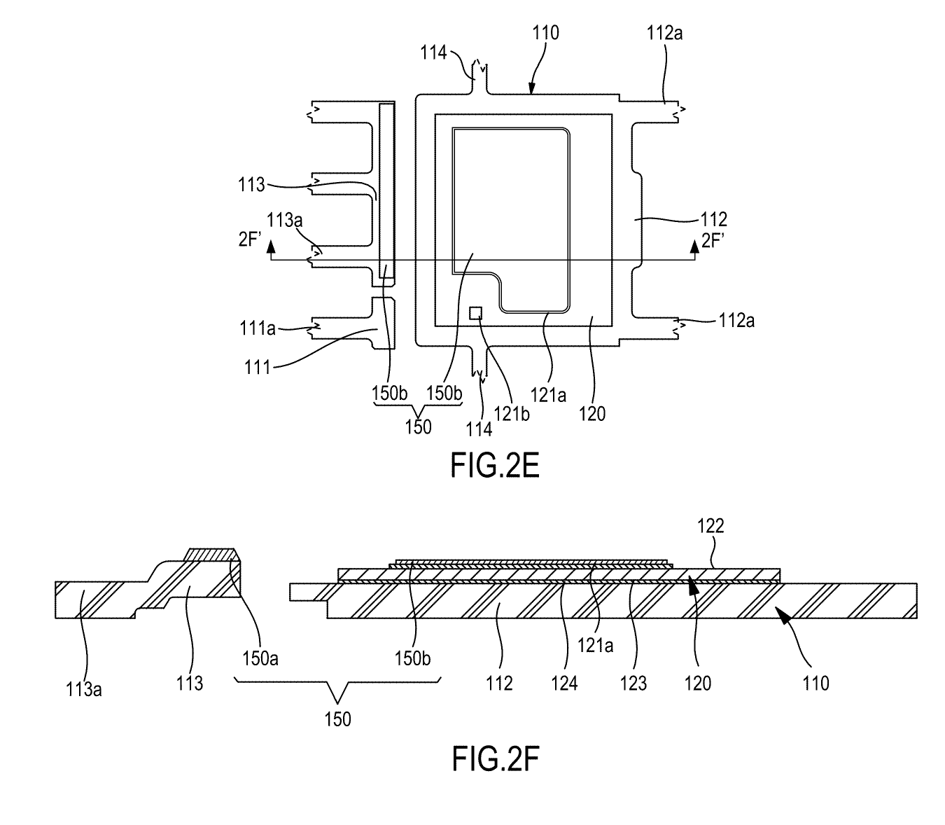

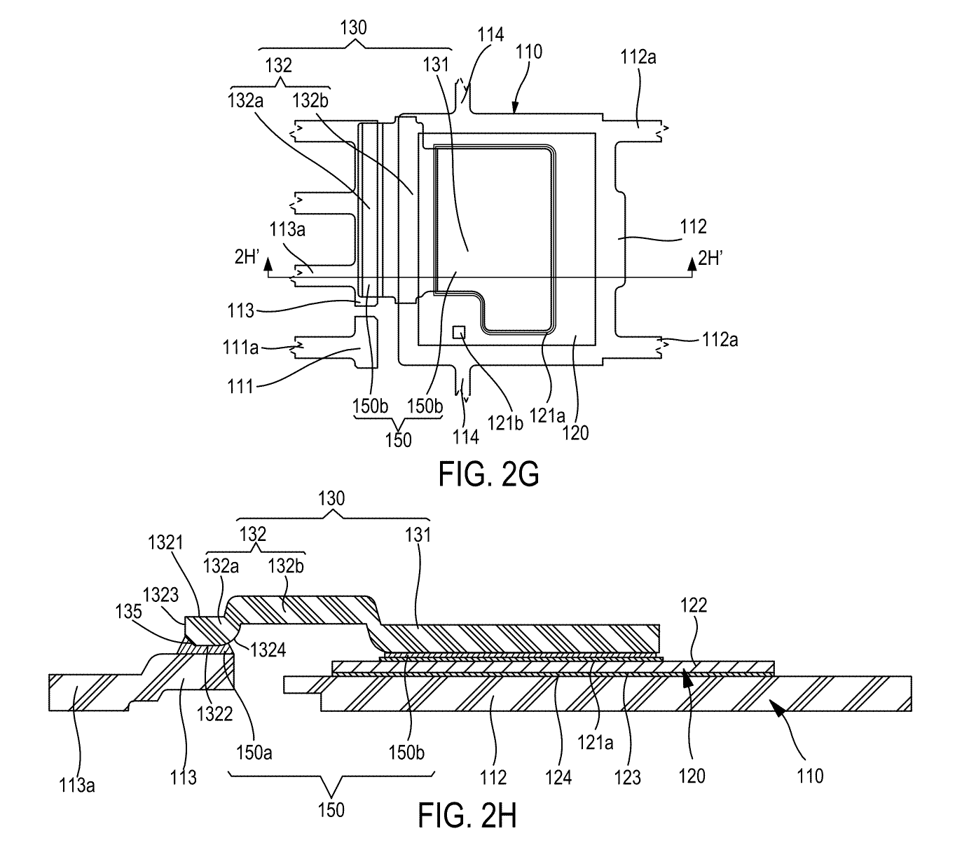

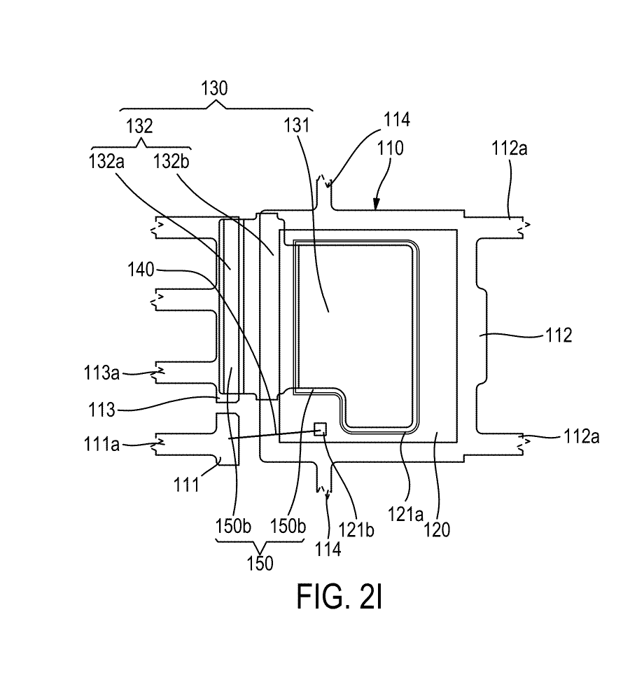

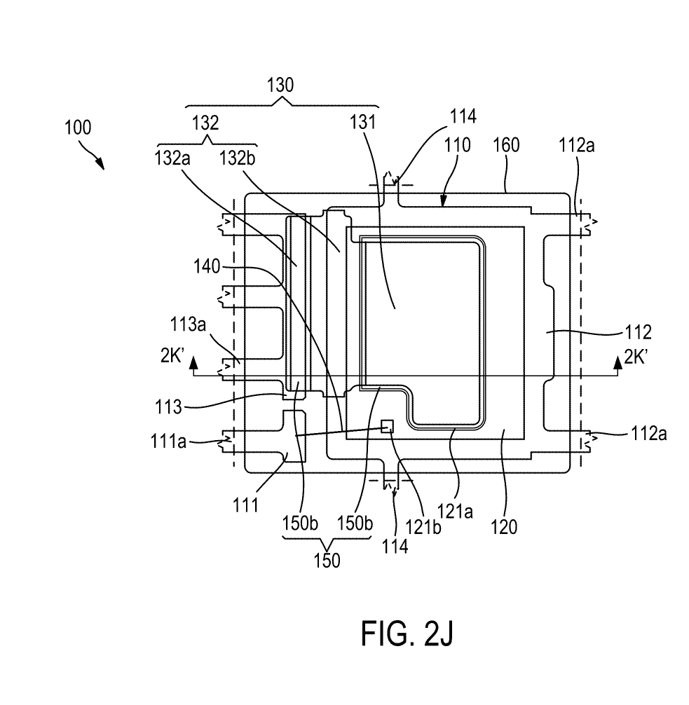

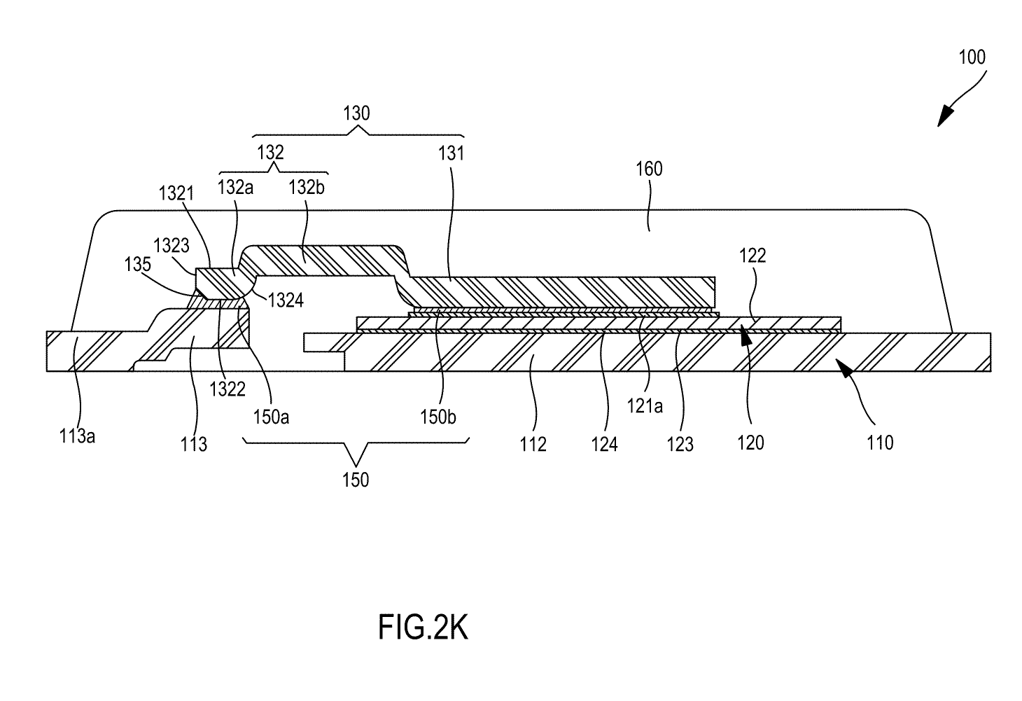

FIGS. 2A, 2B, 2C, 2D, 2E, 2F, 2G, 2H, 2I, 2J, and 2K show an example method for manufacturing an electronic device, such as electronic device 100.

FIGS. 2A and 2B a show top plan view and a cross-sectional view, respectively, of electronic device 100 at early stage of manufacture. The cross-sectional view of FIG. 2B is taken along reference line 2B’-2B’ of FIG. 2A. In the example shown in FIGS. 2A and 2B, substrate 110 can be provided. Substrate 110 can comprise or be referred to as a lead frame or a molded substrate, such as molded lead frame substrate. In some examples, substrate 110 can comprise a conductive material, such as a copper (Cu) alloy (for example, Cu with one of or more of nickel (Ni), silicon (Si), phosphorous (P), or titanium (Ti)), an iron-nickel (FeNi) alloy, or a Cu/stainless steel/Cu clad metal. In some examples, the thickness of substrate 110 can be about 138 microns to about 355 microns. In some examples, substrate 110 is provided using conventional processing techniques, such as etching, stamping, forming, or combinations thereof.

In some examples, substrate 110 can comprise gate contact 111, die paddle 112, and source contact 113. In some examples, substrate 110 can comprise gate outward terminal 111a coupled to and extending outward from gate contact 111. In some examples, substrate 110 can comprise at least one drain outward terminal 112a coupled to and extending outward from die paddle 112. In some examples, substrate 110 can comprise one or more source outward terminals 113a coupled to and extending outward from source contact 113. In some examples, die paddle 112 can be a rectangular plate, and gate contact 111 and source contact 113 can be arranged to be spaced apart from one side of die paddle 112. In some examples, gate contact 111 and source contact 113 are proximate to a first lateral side of die paddle 112 and drain outward terminal 112a extends from a second lateral side of die paddle. In some examples, the second lateral side is opposite to the first lateral side. In some examples, tie bars 114 extend from opposing sides of die paddle 112.

In some examples, gate contact 111 can be provided to be spaced apart from the first lateral side of die paddle 112 and from a lateral side of source contact 113. In some examples, the direction where gate contact 111 is spaced apart from die paddle 112 and the direction where gate contact 111 is spaced apart from source contact 113 can be perpendicular to each other. In some examples, gate contact 111 can be provided in a substantially square plate shape in a top plan view. In some examples, the top side of gate contact 111 can be located above the top side of die paddle 112. In some examples, at least one gate contact 111 can be provided. in other examples, multiple gate contacts 111 can be provided for multi-chip configurations or for current sensing. Gate contact 111 can comprise or be referred to as a gate pad or a gate paddle. Gate contact 111 can serve as a path through which a gate voltage is applied to the gate structure of electronic component 120. In some examples, gate contact 111 can comprise a plated structure on the upper side of gate contact 111. In some examples, the plated structure can comprise Ag. In some examples, the thickness of the plated structure can range from about 1.0 micron to about 8.0 microns. Gate contact 111 can be an example of a second contact.

In some examples, gate outward terminal 111a is coupled to a distal side (for example, outward face side) of gate contact 111 and extends outward from gate contact 111 and die paddle 112. Gate contact 111 is interposed between die paddle 112 and gate outward terminal 111a. In some examples, gate outward terminal 111a can extend downward from one side of gate contact 111 so that the top side of gate outward terminal 111a is below the top side of gate contact 111. In some examples, gate outward terminal 111a can be bent downward together with source outward terminal 113a to facilitate attachment to a next of assembly, such as an external circuit board. Gate outward terminal 111a can be coupled to the external circuit board to provide a gate voltage application path between electronic component 120 and the external circuit board. In some examples, gate outward terminal 111a can be connected to and supported on a frame body through a dam bar being provided intersecting each other during the assembly process. In some examples, the area of gate contact 111 can be about 250 microns x 250 microns to about 1050 microns x 1050 microns. Gate outward terminal 111a can be an example of a second contact outward terminal or a first gate outward terminal.

Die paddle 112 can be spaced apart from a proximate side (for example, inward facing side) of source contact 113 and a proximate side of gate contact 111. In some examples, the proximate side of source contact 113 and the proximate side of gate contact 111 can be located along reference line 1112. In some examples, die paddle 112 can comprise or be referred to as a pad, die pad, or a drain contact. In some examples, die paddle 112 can be supported by a rectangular plate connected to the frame body via at least one tie bar 114 during the assembly process. In some examples, the area of die paddle 112 can vary depending on the area of electronic component 120, and can range from about 1.00 mm (millimeter) x about 1.45 mm to about 4.42 mm x about 4.00 mm.

In some examples, drain outward terminal 112a can be connected to and supported by a frame body with, for example, a dam bar provided across drain outward terminal 112a during the assembly process. In some examples, source outward terminal 113a or gate outward terminal 111a can be connected to and supported by the frame body through a dam bar provided across it. In some examples, the respective ends of drain outward terminals 112a, source outward terminal 113a, or gate outward terminal 111a can be supported through connection to the frame body. In some examples, drain outward terminal 112a is configured to attach to a next level of assembly, such as an external circuit board to provide a drain current flow path between electronic component 120 and the external circuit board. Drain outward terminal 112a can be an example of a first outward terminal or a die paddle outward terminal.

In some examples, source contact 113 can be a rectangular plate and can be provided parallel to the first lateral side of die paddle 112. In some examples, the top side of source contact 113 can be located above the top side of die paddle 112. Source contact 113 can comprise or be referred to as a source pad or a source paddle. Source contact 113 can serve as a path through which current flows from the source region of electronic component 120. Source outward terminals 113a can comprise source outward terminals 113a extending outward from a distal side of source contact 113. Source contact 113 is interposed between die paddle 112 and source outward terminals 113a. In some examples, source outward terminals 113a can each extend in a generally perpendicular direction to the first lateral side of die paddle 112. In some examples, source outward terminals 113a can be bent downward to facilitate attachment to a next level of assembly, such as an external circuit board. In some examples, source outward terminal 113a can be coupled to the external circuit board, thereby providing a current flow path between electronic component 120 and the external circuit board. Source contact 113 can be an example of a first contact and source outward terminal 113a can be an example of a second outward terminal or a first contact outward terminal.

FIGS. 2C and 2D show a top plan and X-ray view and a cross-sectional view, respectively, of electronic device 100 at a later stage of manufacture. The cross-sectional view of FIG. 2D is taken along reference line 2D’-2D’ of FIG. 2C. In the example shown in FIGS. 2C and 2D, electronic component 120 can be provided on the upper side of die paddle 112. For example, the lower side of electronic component 120 can be coupled to die paddle 112. In some examples, the lower side of electronic component 120 comprises a conductor, such as a back metal structure provided as part of electronic component 120 during front-end wafer fabrication.

In some examples, electronic component 120 can be coupled to die paddle 112 through conductive adhesive 124. For example, conductive adhesive 124 can comprise or be referred to as solder. In some examples, conductive adhesive 124 can comprise tin (Sn), silver (Ag), lead (Pb), Cu, Sn-Pb, Sn37-Pb, Sn95-Pb, Sn-Pb-Ag, Sn-Cu, Sn-Ag, tin-gold (Sn-Au), tin-bismuth (Sn-Bi), or Sn-Ag-Cu, In some examples, after conductive adhesive 124 is provided on the upper side of die paddle 112, electronic component 120 can be seated on the upper side of conductive adhesive 124. Thereafter, a reflow process or a thermal compression process is used to electrically/mechanically/thermally or mechanically/thermally connect electronic component 120 to die paddle 112. In some examples, the thickness of conductive adhesive 124 can range from 20 microns to about 50 microns. Conductive adhesive 124 can be provided using conventional techniques, such as dispensing, laminating, preform attaching, or printing techniques.

Electronic component 120 can comprise first side 122 and second side 123 opposite to first side 122. In some examples, first side 122 of electronic component 120 can comprise or be referred to as an active side where doped regions and interconnects are provided, and second side 123 of electronic component 120 can comprise or be referred to as a lower side. In the present example, second side 123 is configured as a drain side of electronic component 120. Electronic component 120 can comprise lateral sides connecting first side 122 and second side 123. In some examples, electronic component 120 can comprise or be referred to as a die, a chip, or a package. First side 122 is an example of a first component side and second side 123 is an example of a second component side.

Electronic component 120 can comprise or be referred to as an active device or a passive device. In some examples, electronic component 120 can comprise a metal-oxide semiconductor field effect transistor device (MOSFET) and can include a source region and a gate region provided on first side 122 and can comprise a drain region provided on second side 123. In the present example, electronic component 120 includes contact pad 121a coupled to the source region and contact pad 121b coupled to the gate region. Contact pad 121a can comprise or be referred to as a source pad or a source bond pad and contact pad 121b can comprise or be referred to as a gate pad or a gate bond pad. The drain region of electronic component 120 can be coupled d to die paddle 112 through a back metal structure and conductive adhesive 124. In other examples, electronic component 120 can comprise an insulated-gate bipolar transistor (IGBT), a thyristor device, or a bipolar junction transistor (BJT). Electronic component 120 can transmit or block current from the source region to the drain region depending on the gate voltage applied to the gate region. Electronic component 120 can comprise a semiconductor material such as silicon; IV-IV materials, such as silicon carbide, silicon-germanium, or carbon doped silicon-germanium; or III-V materials, such as gallium-nitride materials.

In some examples, the thickness of electronic component 120 can range from about 55 microns to about 95 microns. In some examples, the area of electronic component 120 can be smaller than the area of die paddle 112 and can be about 0.70 mm x about 1.15 mm to about 4.12 mm x about 3.70 mm.

FIGS. 2E and 2F show a top plan and X-ray view and a cross-sectional view, respectively, of electronic device 100 at a later stage of manufacture. The cross-sectional view of FIG. 2F is taken along reference line 2F’-2F’ of FIG. 2E. In the examples shown in FIGS. 2E and 2F, conductive adhesive 150 can be provided on first side 122 of electronic component 120 and the upper side of source contact 113, respectively. In some examples, conductive adhesive 150 is provided on contact pad 121a.

Conductive adhesive 150 can comprise first conductive adhesive 150a provided on the upper side of source contact 113 and second conductive adhesive 150b provided on the upper side of contact pad 121a. In some examples, first conductive adhesive 150a and second conductive adhesive 150b can comprise or be referred to as a solder. In some examples, conductive adhesive 150 can have corresponding elements, features, materials, or manufacturing methods similar to those of conductive adhesive 124.

In some examples, first conductive adhesive 150a can be in contact with and connected to source contact 113 of substrate 110. In some examples, the thickness of first conductive adhesive 150a can range from about 1 micron to about 20 microns. Second conductive adhesive 150b can be in contact with and connected to the contact pad 121a of electronic component 120. In some examples, the thickness of second conductive adhesive 150b can range from about 8 microns to about 20 microns.

FIGS. 2G and 2H show a top plan and X-ray view and a cross-sectional view, respectively, of electronic device 100 at a later stage of manufacture. The cross-sectional view of FIG. 2H is taken along reference line 2H’-2H’ of FIG. 2G. In the examples shown in FIGS. 2G and 2H, conductive connect 130 can be provided to cover conductive adhesive 150. For example, after conductive connect 130 is placed onto or seated on first conductive adhesive 150a and second conductive adhesive 150b, a reflow process or a thermal compression process can be performed, and thus conductive connect 130 can be electrically/mechanically/thermally connected to substrate 110 and electronic component 120. In some examples, conductive connect 130 comprises connect plate portion 131 and connect leg 132. In some examples, connect leg 132 comprises foot portion 132a coupled to leg portion 132b, which is further coupled to connect plate portion 131.

In the present example, foot portion 132a is coupled to source contact 113 with first conductive adhesive 150a and connect plate portion 131 is coupled to contact pad 121a of electronic component 120 with second conductive adhesive 150b. Conductive connect 130 can couple source contact 113 of substrate 110 to the source region of electronic component 120. In the present example, the top side of leg portion 132b resides on a first plane, the top side of foot portion 132a resides on a second plane, and the top side of connect plate portion 131 resides a third plane. In some examples, the first plane is above the second plane and the third plane. In some examples, the second plane is above the third plane. In the present example, leg portion 132b is offset upward with respect to connect plate portion 131 and offset upward with respect to foot portion 132a. In some examples, conductive connect 130 can comprise or be referred to as a clip, a clip interconnect, a conductive strap, or a conductive clip. In some examples, conductive connect 130 comprises Cu or a Cu alloy. In some examples, the thickness of conductive connect 130 can range from about 150 microns to about 250 microns.

First conductive adhesive 150a can be interposed between bottom side 1322 of foot portion 132a and the upper side of source contact 113. Second conductive adhesive 150b can be interposed between the upper side of contact pad 121a and the lower side of connect plate portion 131. In the present example, foot portion 132a comprises chamfer 135 that extends inward from outward lateral side 1323 of foot portion 132a and terminates at a location at bottom side 1322 of foot portion 132a. In some examples, chamfer 135 can be provided by partially removing the lower outward corner portion of foot portion 132a. In the present example, chamfer 135 is in contact with and is covered by first conductive adhesive 150a. Chamfer 135 can be located distal to connect plate portion 131 and can extend to the bottom side of foot portion 132a along the direction where source contact 113 extends. In some examples, chamfer 135 can be provided only in a partial area along the direction where source contact 113 extends. In some examples, the inclined width of chamfer 135 can be about 45 microns to about 95 microns, and the inclined height can be about 45 microns to about 95 microns. Chamfer 135 is provided at an angle (for example, element 32 of FIG. 1C) with respect to outward lateral side 1323 of foot portion 132a that is greater than 0 degrees and less than 90 degrees. In some examples, the angle is between about 25 degrees and about 65 degrees. In some examples, the angle is between about 30 degrees and about 60 degrees. In some examples, the angle is between about 40 degrees and about 50 degrees. In some examples, the angle is about 45 degrees. Chamfer 135 can have other features as described with FIG. 1C.

In accordance with the present description, foot portion 132a of connect leg 132 can be provided with chamfer 135 to increase the amount of first conductive adhesive 150a between source contact 113 of substrate 110 and connect leg 132, thereby increasing the bonding strength between substrate 110 and conductive connect 130. Conductive connect 130 can be provided with chamfer 135 to increase the amount of first conductive adhesive 150a, thereby preventing substrate 110 and conductive connect 130 from being separated from each other due to the stress applied during thermal cycles where deformation occurs with expansion and contraction.

FIG. 2I shows top plan and X-ray view of electronic device 100 at a later stage of manufacture. In the example shown in FIG. 2I, interconnect 140 can be provided between gate contact 111 of substrate 110 and contact pad 121b of electronic component 120 to couple gate contact 111 to contact pad 121b.

In some examples, interconnect 140 can comprise or be referred to as a conductive wire. In some examples, interconnect 140 can comprise Cu and can be coated with Au, Cu, aluminum (Al), or palladium (Pd). In some examples, wire bonding equipment can be used to ball-bond interconnect 140 to contact pad 121b of electronic component 120 and stitch-bond interconnect 140 to gate contact 111 of substrate 110. Interconnect 140 can couple substrate 110 to electronic component 120 and provide a signal path between substrate 110 and electronic component 120. In some examples, the thickness of interconnect 140 can range from about 45 microns to about 55 microns.

In some examples, the gate region of electronic component 120 can be coupled to gate contact 111 and gate outward terminal 111a through contact pad 121b and interconnect 150, and the drain region of electronic component 120 can be coupled to die paddle 112 and drain outward terminal 112a through conductive adhesive 124, and the source region of electronic component 120 can be coupled to source contact 113 and source outward terminal 113a through contact pad 121a, conductive adhesive 150, and conductive connect 130.

FIGS. 2J and 2K show a top plan and X-ray view and a cross-sectional view of electronic device 100 at a later stage of manufacture. The cross-sectional view of FIG. 2K is taken along reference line 2K’-2K’ of FIG. 2J. In the examples shown in FIGS. 2J and 2K, encapsulant 160 can be provided to encapsulate substrate 110, electronic component 120, conductive connect 130, and interconnect 140. Encapsulant 160 can comprise or be referred to as an epoxy molding compound, a resin, a filler-reinforced polymer, a B-stage compressed film, or gel.

In some examples, encapsulant 160 can be provided by compression molding, transfer molding, liquid encapsulant molding, vacuum lamination, paste printing, or film assisted molding. Compression molding can be a process of supplying a fluid resin to a mold in advance and then putting the substrate 110 into the mold to cure the fluid resin, and transfer molding can be a process of supplying a resin to the vicinity of substrate 110 by using a gate (a supply port). After this process, the cured encapsulant 160 can be ejected from the mold.

In some examples, encapsulant 160 covers substrate 110, electronic component 120, conductive connect 130, and interconnect 140. In some examples, portions of gate outward terminal 111a, drain outward terminal 112a, source outward terminal 113a, or tie bars 114, can protrude or be exposed from lateral sides or the lower side of encapsulant 160. In some examples, the lower side of substrate 110 can be exposed from the lower side of encapsulant 160. In some examples, the lower side of substrate 110 and the lower side of encapsulant 160 can be coplanar. In some examples, the thickness of encapsulant 160 can range from about 0.9 mm to about 1.1 mm. Encapsulant 160 can isolate and protect substrate 110, electronic component 120, conductive connect 130, and interconnect 140 from external environments.

In some examples, a plating process can be performed after the encapsulation process. Solder, Ni, Pd, or Au can be plated on the surfaces of gate outward terminal 111a, drain outward terminal 112a, and source outward terminal 113a exposed from encapsulant 160 to protect these surfaces from corrosion. In some examples, solder wettability can also be improved. In some examples, when a lead frame substrate having pre-plated frame (PPF) technology applied is used for substrate 110, the plating process can be omitted.

In some examples, a trim/forming process can be performed after the encapsulation process. In some examples, substrate 110 can be subjected to the trim/forming process by being placed in a trim/forming device. In some examples, the end of gate outward terminal 111a, the end of drain outward terminal 112a, and the end of source outward terminal 113a, which are connected to the frame body, can be cut. The dam bar connecting the terminals to each other can be removed by cutting. In some examples, gate outward terminal 111a, drain outward terminal 112a, and source outward terminal 113a can be bent into a predetermined shape to facilitate attachment to a next level of assembly, such as external circuit board.

In some examples, a punching process can be performed after the trim/forming process. In some examples, after substrate 110 is placed on punching equipment, at least one tie bar 114 connecting electronic device 100 and the frame body can be removed, thereby allowing electronic device 100 to finally become independent from the frame body. Although the manufacturing process of one electronic device 100 has been described, multiple electronic devices 100 can be manufactured from one frame body.

In summary, structures and methods have been described that relate to packaged electronic components having improved manufacturability, quality, and reliability. More particularly, structures and methods have been described that improve bonding integrity between conductive connects and substrates used to support electronic components. In some examples, the conductive connect includes a chamfered edge provided at a foot portion, which was found through experimentation to improve the bonding integrity between the foot portion and substrate lead(s) by facilitating a larger solder fillet proximate to the chamfered edge. In some examples, the chamfered edge accommodates additional conductive adhesive between the substrate and the conductive connect thereby increasing the bonding strength between the substrate and conductive connect. Among other things, this reduces the likelihood of separation between substrate and conducive connect due to the stress applied during thermal cycles where deformation occurs with expansion and contraction. This improves the manufacturability, quality, and reliability of packaged electronic components, such as power semiconductor devices.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising:
a die paddle; and
a first contact spaced apart from the die paddle;
an electronic component comprising:
a first component side; and
a second component side opposite to the first component side and coupled to the die paddle;
a conductive adhesive;
a conductive connect comprising:
a foot portion coupled to the first contact with the conductive adhesive, the foot portion comprising:
a top side;
a bottom side opposite to the top side;
an outward lateral side; and
a chamfer that extends inward from the outward lateral side and terminates at a location at the bottom side,
wherein:
the conductive adhesive contacts the chamfer and the bottom side; and
a connect plate portion coupled to the first component side; and
an encapsulant covering the electronic component, the conductive connect, and at least portions of the substrate.

2. The electronic device of claim 1, wherein:
the conductive connect comprises a leg portion;
the foot portion is coupled to the leg portion; and
the connect plate portion is coupled to the leg portion.

3. The electronic device of claim 2, wherein:
the leg portion comprises a leg portion top side that resides on a first plane;
the top side of the foot portion resides on a second plane;
the connect plate portion comprises a connect plate portion top side that resides on a third plane; and
the second plane and the third plane are below the first plane.

4. The electronic device of claim 1, further comprising:
a first outward terminal coupled to the first contact;
wherein:
the first outward terminal is exposed from a lateral side and a bottom side of the encapsulant.

5. The electronic device of claim 1, wherein:
the chamfer starts at a location on the outward lateral side that leaves at least 50% of the outward lateral side extending downward from the top side.

6. The electronic device of claim 1, wherein:
the chamfer is provided at an angle with respect to the outward lateral side; and
the angle is between about 30 degrees and about 60 degrees.

7. The electronic device of claim 1, wherein:
the outward lateral side comprises a first center point in a cross-sectional view;
the bottom side comprises a second center point in the cross-sectional view; and
the chamfer starts at a location on the outward lateral side that is below the first center point and ends at a location on the bottom side that is left of the second center point.

8. The electronic device of claim 1, wherein:
the chamfer is continuous and uninterrupted without breaks along an entire length of the outward lateral side.

9. The electronic device of claim 1, wherein:
the chamfer comprises a plurality of chamfers that are separated by portions of the outward lateral side.

10. The electronic device of claim 9, wherein:
the foot portion comprises opposing ends; and
at least one of the opposing ends is defined by one of the plurality of chamfers.

11. The electronic device of claim 1, wherein:
the first contact comprises a first contact top side; and
the top side of the foot portion is parallel to the first contact top side.

12. The electronic device of claim 1, wherein:
the conductive adhesive comprises an outward side that extends towards the first contact in a first direction; and
the chamfer extends towards the first contact in second direction that is different than the first direction.

13. The electronic device of claim 1, wherein:
the first contact comprises a first contact outward terminal exposed from the encapsulant;
the die paddle comprises a die paddle outward terminal exposed from the encapsulant;
the substrate further comprises a second contact spaced apart from the die paddle;
the second contact comprises a second contact outward terminal exposed from the encapsulant; and
the electronic component is coupled to the second contact.

14. An electronic device, comprising:
a substrate comprising:
a die paddle;
a first contact spaced apart from the die paddle and comprising a first contact top side;
a first outward terminal coupled to the first contact;
a second contact spaced apart from the die paddle; and
a second outward terminal coupled to the second contact;
an electronic component comprising:
a first component side; and
a second component side opposite to the first component side and coupled to the die paddle;
a conductive adhesive;
a conductive connect comprising:
a foot portion coupled to the first contact with the conductive adhesive, the foot portion comprising:
a top side;
a bottom side opposite to the top side;
an outward lateral side;
an inward lateral side opposite the outward lateral side; and
a chamfer that extends inward from the outward lateral side and terminates at a location at the bottom side,
wherein:
the conductive adhesive covers the chamfer and the bottom side; and
the top side of the foot portion is generally parallel to the first contact top side; and
a connect plate portion coupled to the first component side; and
an encapsulant covering the electronic component, the conductive connect, and at least portions of the substrate, wherein the first outward terminal and the second outward terminal are exposed from the encapsulant.

15. The electronic device of claim 14, wherein:
the outward lateral side and the inward lateral comprise different shapes in a cross-sectional view;
the conductive connect comprises a leg portion;
the foot portion is coupled to the leg portion;
the connect plate portion is coupled to the leg portion;
the leg portion comprises a leg portion top side that resides on a first plane;
the top side of the foot portion resides on a second plane;
the connect plate portion comprises a connect plate portion top side that resides on a third plane; and
the second plane and the third plane are below the first plane.

16. The electronic device of claim 14, wherein:
the chamfer starts at a location on the outward lateral side of the foot portion that leaves at least 25% to 75% of the outward lateral side extending downward from the top side of the foot portion.

17. The electronic device of claim 14, wherein:
the chamfer comprises an inclined width from about 45 microns to about 95 microns.

18. A method of manufacturing an electronic device, comprising:
providing a substrate comprising:
a die paddle; and
a first contact spaced apart from the die paddle;
providing an electronic component comprising:
a first component side; and
a second component side opposite to the first component side and coupled to the die paddle;
providing a conductive adhesive;
providing a conductive connect comprising:
a foot portion coupled to the first contact with the conductive adhesive, the foot portion comprising:
a top side;
a bottom side opposite to the top side;
an outward lateral side; and
a chamfer that extends inward from the outward lateral side and terminates at a location at the bottom side,
wherein:
the conductive adhesive contacts the chamfer and the bottom side; and
a connect plate portion coupled to the first component side; and
providing an encapsulant covering the electronic component, the conductive connect, and at least portions of the substrate.

19. The method of claim 18, wherein:
providing the conductive connect comprises providing the chamfer continuous and uninterrupted without breaks along an entire length of the outward lateral side.

20. The method of claim 18, wherein:
providing the conductive connect comprises providing the chamfer comprising a plurality of chamfers that are separated by portions of the outward lateral side.
